(19) United States
(12) Patent Application Publication
(10) Pub. No.: US 2015/0042218 A1
(43) Pub. Date: Feb. 12, 2015

(54) HOUSING FOR A DEVICE

(71) Applicant: Thor Berge Mevatne, Notteroy (NO)

(72) Inventor: Thor Berge Mevatne, Notteroy (NO)

(73) Assignee: BERGE SOLUTIONS AS, Tønsberg (NO)

(21) Appl. No.: 14/346,935

(22) PCT Filed: Aug. 10, 2012
(86) PCT No.: PCT/NO2012/050147

§ 371 Date: Jul. 23, 2014

(30) Foreign Application Priority Data
Sep. 23, 2011 (NO) 20111299

(51) Int. Cl. H05K 5/06; H05K 5/00; H05K 9/00; H05K 5/03

(52) U.S. Cl. CPC H05K 5/062; H05K 5/03; H05K 5/0004; H05K 9/0015
USPC 312/223.1; 264/571; 264/263

(57) ABSTRACT

There is disclosed a housing for electronic devices. The housing is assembled from several components (if 2). The components form a continuous closed section gasket channel (4, 9) there between. A suitable fluid is injected into said channel to form a gasket between the components.

### FIELD OF THE INVENTION

The present invention relates to a housing intended to encapsulate delicate equipment against harsh environments.

### BACKGROUND

At times, electronic devices are installed in harsh environments, such as production plants, the drill deck of an offshore platform or in ships. Special housings are needed for the devices, to protect against water ingress or an explosive atmosphere. The devises in question may be control panels, computers, or display units. Normally, this is standard equipment such as personal computers that is installed in special encapsulations with heavy walls and covers closed with rubber gaskets. Such encapsulations are very voluminous and expensive.

The present inventor produces computers for use on ships' bridges. The computers are used to present navigational information to the pilot or helmsman. The current solution is to cast the computer components into a compact block using a suitable polymer. However, in order to install components that protrude from the housing, such as pressure switches (“buttons”) or contacts, the casting must be made in several steps. Since the polymer must cure between each step, the production process is time consuming.

### SUMMARY OF THE INVENTION

It is an object of the present invention to provide a housing that at least partly remedies the above mentioned drawbacks.

This is obtained in a housing according to the appended claims. Briefly, the inventive housing is composed of a number of individual parts, the parts forming a continuous channel there between when assembled. A gasket fluid is injected into said channel gluing the parts together.

### BRIEF DESCRIPTION OF THE DRAWINGS

The invention will now be described in detail in reference to the appended drawings, in which:

FIG. 1 is an exploded view of an embodiment of the invention,

FIG. 2a and b illustrates the inventive concept,

FIG. 3 shows a flow channel in said embodiment of the invention,

FIG. 4 shows another detail of the invention.

### DETAILED DESCRIPTION

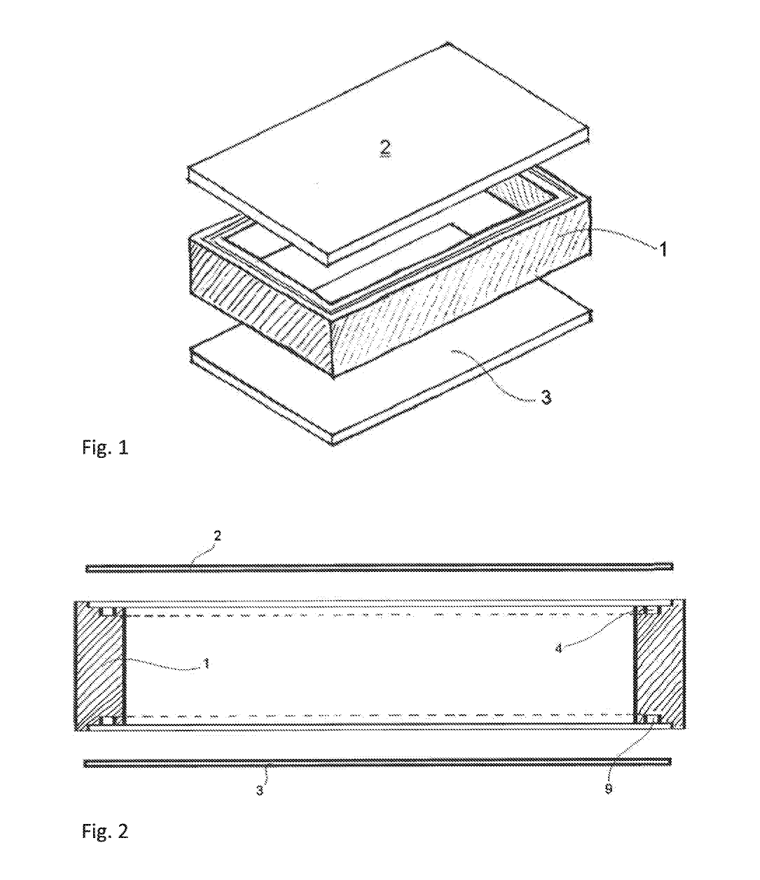

FIG. 1 illustrates an embodiment of the invention wherein several parts are assembled into a rectangular housing for an electronic device. The housing includes a rectangular frame 1 closed by a top covering plate 2 and a bottom covering plate 3. In the top and bottom surfaces of the frame 1 there are grooves 4 for holding gaskets. The grooves may be formed when casting the frame, or by milling. These grooves will form closed section channels when the covers are fitted to the frame, as illustrated in FIG. 2a, b. The groove in the top surface will form a first gasket channel 4, while the groove in the bottom surface will form a second gasket channel 9. The first gasket channel 4 is connected to an inlet channel 5. A transfer channel 8 interconnects the first gasket channel 4 and the second gasket channel 9. The second gasket channel 9 is connected to an outlet channel 6.

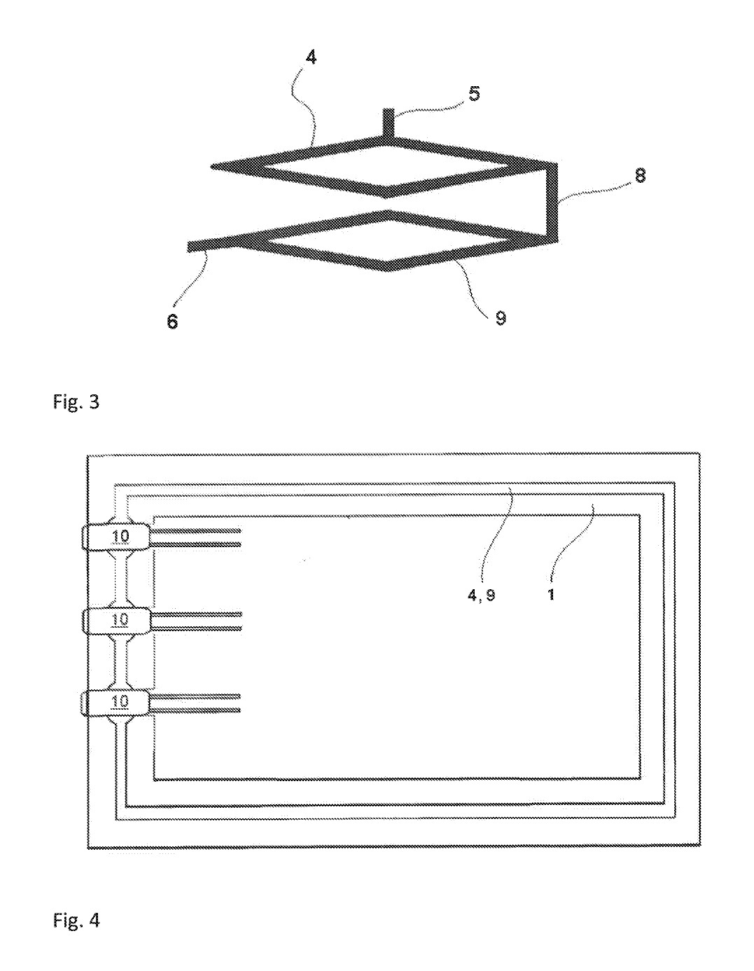

These channels will form a continuous flow loop from the inlet to the outlet, as depicted in FIG. 3. To introduce the gasket, the parts are clamped together and a gasket fluid injected through the inlet channel 5. The gasket fluid will fill the gasket channels and eventually arrive at the outlet channel. The further process is dependent on the properties of the gasket fluid that is employed.

In a preferred embodiment of the invention, the gasket fluid is of a type that will cure into a hard mass gluing the parts together. Thus, no fastening means are needed to hold the parts together, when the clamping means are removed. However, the finished housing may be hard, if not impossible, to disassemble, which may preclude any service to the innards. Nowadays this may not be regarded as a major drawback as the falling prices on electronic devices allow faulty devices to be replaced. The gasket fluid may also have the property of curing into a flexible gasket gluing the parts together. Having a flexible gasket may be advantageous for dampening vibrations in the housing.

In a second embodiment, the parts are assembled with suitable fastening means, such as screws, and a gasket fluid that will cure into an elastic and flexible mass is injected through the inlet channel. The gasket will make the housing watertight, but not glue the parts together. This embodiment has the advantage that the housing may be opened later on for service, and the gasket replaced.

In a third embodiment, the gasket fluid is of a type that will remain fluid, as a viscous liquid. The various parts are fitted and fastened together forming the housing, the gasket fluid injected through the inlet channel, and the inlet and outlet channels plugged.

FIG. 4 shows how a component penetrating the housing may be installed as a part of the assembly. The component in question may be a switch, a contact, or a component with a shaft to be maneuvered from outside the housing, such as an encoder, potentiometer or variable capacitor. The component may be installed in a bore with a surrounding groove, the groove being formed in the adjacent part(s) or in the component itself, the groove being part of the channel loop receiving the gasket fluid.

The gasket fluid may have additional properties as needed for the intended use of the housing. The gasket may be made conductive, by adding a conductive component to the fluid, to let the housing act as a shield. An agent with high magnetic permeability may be added, such as dust of soft iron or mu metal, in order to obtain a protection against EMI (Electro Magnetic Interference). The gasket may also be made transparent or translucent, to allow the gasket to act as a light guide, e.g. for transferring signals between components of the device inside the housing, or to transfer light signals to the outside or vice versa, either for communication or as visible signals to the user.

The core component of the gasket fluid may be polyurethane, silicone, epoxy resin, or any polymer suited for the purpose.

The housing may be assembled from parts made from metal, plastics or reinforced plastics, or a mixture of the same. In the embodiment shown I FIG. 1, all parts may be made from a metal, such as aluminum or a sink alloy, or the frame may be in reinforced plastic and the covers in metal.

The embodiment illustrated in FIG. 1 includes two gasket channels 4, 9 connected via the transfer channel 8. However, in other cases only one gasket channel may be sufficient, i.e. when fitting a cover to a box with a closed bottom. In other cases the housing may include several gaskets interconnected with transfer channels. The point is to establish a continuous series of interconnected channels allowing the gasket fluid to be injected and flow through the whole loop system and fill all the channels. The channels may be designed so as to avoid the formation of air pockets. Alternatively, additional outlet channels may be added in order to allow trapped air to escape, the assembly may be rotated during injection of the fluid, or the gasket fluid may be injected using vacuum. However, these techniques are well known for persons skilled in the art of casting. The fluid may be introduced into the channels simply by pouring the fluid into the inlet channel, instead of pressurized injection. Then, additional outlet channels may allow the fluid to rise evenly in the channels and fill them fully. Thus, the term injection here means both passive pouring and injection by pressure.

To strengthen the bond between the parts, opposing parts may each include grooves that are dovetail-shaped in cross section. The resulting channel will then be hourglass-shaped in cross section (not shown). Another option is to include projections in some of the parts protruding into the grooves of opposing parts. The projections may e.g. be harpoon-shaped in cross section, thus anchoring the parts together in the gasket fluid (not shown).

While the invention has been described as a housing particularly suited for electronic devices, the housing may be used for any delicate device that must be protected against a hostile environment. Examples of devices that may benefit from the invention may be clock works, cameras, keyboards, mobile phones, handheld computers or instruments in general. Such instruments may be the instruments in the dashboard of a car. If the instruments are mounted in a housing according to the invention, formation of dew inside the instrument may be avoided. Other applications may be housing instruments aboard a sailing boat, or instruments to be used in the field, e.g. by land surveyors.

1. A housing for a device, said housing including a first part and at least a second part, at least one of said parts including a groove, wherein said parts define a first closed section gasket channel loop there between when the parts are assembled to form said housing, an inlet channel communicating with the first gasket channel loop,
characterized in a transfer channel connecting said first gasket channel loop to a second gasket channel loop or a series of communicating additional gasket channel loops,
said first and second parts and/or one or more additional parts include additional grooves defining the second gasket channel loop there between or the series of gasket channel loops,
an outlet channel communicating with the second gasket channel loop or a last gasket channel loop in a series of gasket channel loops, and
a gasket fluid to be injected through said inlet channel filling said inlet channel, first gasket channel loop, transfer channel, possible additional gasket channel loops and outlet channel forming a continuous gasket between said parts, the gasket fluid being adapted to cure and glue said parts together.

2. (canceled)

3. A housing according to claim 1, wherein the gasket fluid includes an Electro Magnetic Interference protecting component, a conductive component, or both the Electro Magnetic Interference protecting component and the conductive component.

4. A housing according to claim 1, wherein the gasket fluid is adapted to cure into a transparent or translucent gasket adapted to act as a light guide for transferring light signals.

5. A housing according to claim 1, further including a component penetrating the housing, the component being installed in a bore in the groove in at least one of the parts, the component being surrounded by the gasket in said groove.

6. A housing according to claim 1, wherein there are opposing grooves in each part, the grooves being dovetail shaped in cross section causing the formation of a gasket that is hourglass shaped in cross section.

7. A housing according to claim 1, wherein at least one of the parts includes projections protruding into the groove of an opposing part.

8. A method for housing devices, the housing including several parts, including the steps of
providing grooves along an outer rim of one or more parts,
temporarily clamp the parts against each other with clamping means, the grooves forming a continuous set of channels with an inlet channel communicating with a first gasket channel loop, a transfer channel communicating with the first gasket channel loop and a second gasket channel loop, and an outlet channel communicating with the second gasket channel loop or the last gasket channel loop in a series with communicating gasket channels loops,
injecting a gasket fluid into the inlet channel until gasket fluid exits from the outlet channel,
curing the gasket fluid gluing the parts together, and
removing the clamping means.

9. A method according to claim 8, wherein the injection step is performed in vacuum.
